(19) United States
(12) Patent Application Publication
(10) Pub. No.: US 2026/0265915 A1
(43) Pub. Date: Sep. 10, 2026

(54) AMPOULE BLOCKER

(71) Applicant: Applied Materials, Inc., Santa Clara, CA (US)

(72) Inventors: Hao ZHUANG, Santa Clara, CA (US); Aixi ZHANG, Santa Clara, CA (US); Bingqian LIU, Santa Clara, CA (US); Yi XU, San Jose, CA (US); Yu LEI, Belmont, CA (US); Rongjun WANG, Dublin, CA (US)

(21) Appl. No.: 19/073,818

(22) Filed: Mar. 7, 2025

(51) Int. Cl. C23C 16/455

(52) U.S. Cl. CPC C23C 16/45561; C23C 16/45544

(57) ABSTRACT

In one or more embodiments, a precursor delivery system includes a container and a blocker inserted into the cavity of the container. The blocker defines a frustum-shaped region, the frustum-shaped region including a first opening positioned at a first end of the frustum-shaped region and a second opening positioned at a second end of the frustum-shaped region. The first end is positioned a distance below the second end. The first opening includes a first area and the second opening includes a second area.

### BACKGROUND

### Field

Embodiments described herein generally relate to improving the uniformity of the dosage of precursor that flows from an ampoule to another process chamber or process environment.

### Description of the Related Art

In many instances, ampoules provide a vaporized precursor material to a process system for the processing of a substrate. For example, a carrier gas may be flowed into the ampoule as the ampoule is heated in order to agitate the precursor and cause the vaporized precursor to flow through an output of the ampoule. A common issue in this process is a varying dosage of the vaporized precursor delivered to another process chamber through the output of the ampoule as the amount of precursor in the ampoule decreases over time. During operation, the precursor is consumed as it vaporizes and flows through the output of the ampoule. As solid types of precursors are consumed, the exposed surface area decreases due to agglomeration or sintering of the solid precursor material (e.g., powder particles), at least partially due to the exposure of the precursor material to heat. Accordingly, the amount of precursor that vaporizes decreases over time. The decrease in the amount of precursor that vaporizes results in less vaporized precursor being entrained into the flowing carrier gas and leads to the delivery of uneven precursor compositions during operation of the ampoule.

Uneven precursor compositions may lead to various processing issues in processing chambers. For example, in the semiconductor industry an ampoule is used to vaporize a precursor before the precursor is provided to a showerhead for deposition on a wafer. As the precursor is consumed and/or sinters, the amount of precursor that vaporizes decreases. As a result, the thickness of the deposited material on the wafers will vary. The earlier batches of wafers will include thicker deposited films. However, as the precursor is consumed, the later batches of wafers will include thinner deposited films.

Conventional attempts to create a steady flow of the vaporized precursor include increasing the temperature of the ampoule and pretreating the ampoule. Increasing the temperature may compensate for the varying dosage of precursor delivered to a process chamber. However, increasing the temperature is costly and it may take a large amount of time for the temperature to stabilize after the temperature is increased. Furthermore, some conventional methods involving a solid precursor include pretreating the ampoule to sinter the solid precursor into larger pieces. Pretreating the ampoule minimizes the decrease in the amount of precursor that is vaporized by limiting the amount of sintering that will occur later. However, pretreating the ampoule is a very long process and the results of several pretreated batches may be inconsistent.

Thus, there is a need for an improved ampoule that allows for a consistent delivery of vaporized precursor to another process chamber or process environment.

### SUMMARY

Embodiments described herein generally relate to precursor delivery systems. More specifically, embodiments described herein relate to a blocker that is inserted into an ampoule or other vessel to steady the dosage of precursor flowing to deposition chambers or other process chambers.

In one or more embodiments, a precursor delivery system includes a container and a blocker inserted into the cavity of the container. The blocker defines a frustum-shaped region, the frustum-shaped region including a first opening positioned at a first end of the frustum-shaped region and a second opening positioned at a second end of the frustum-shaped region. The first end is positioned a distance below the second end. The first opening includes a first area and the second opening includes a second area.

In one or more embodiments, a method of forming an ampoule includes forming a container, wherein the container includes a lid with an inlet port and an outlet port, at least one sidewall, a bottom, and a cavity defined as the space enclosed by the lid, sidewall(s), and bottom. The method further includes inserting a blocker inside the cavity of the container, the blocker includes a frustum-shaped region, wherein the frustum-shaped region includes a first opening positioned at a first end of the frustum-shaped region and a second opening positioned at a second end of the frustum-shaped region. The first end is positioned a distance below the second end. The first opening includes a first area and the second opening includes a second area.

In one or more embodiments, an ampoule blocker is positioned inside a container coupled to a deposition chamber. The ampoule blocker includes a solid material defined by a frustum-shaped cavity. The frustum-shaped cavity includes a first opening positioned at a first end of the frustum-shaped cavity and a second opening positioned at a second end of the frustum-shaped cavity. The first end is positioned a distance below the second end. The first opening includes a first area and the second opening includes a second area.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A illustrates a perspective view of a cylindrical-shaped ampoule with a blocker, according to one or more embodiments of the disclosure.

FIG. 1B illustrates a perspective view of a rectangular prism-shaped ampoule with a blocker, according to one or more embodiments of the disclosure.

FIG. 1C illustrates a perspective view of a combination rectangular prism-shaped and triangular prism-shaped ampoule with a blocker, according to one or more embodiments of the disclosure.

FIG. 2A illustrates a side cross-sectional view of an ampoule with a blocker, according to one or more embodiments of the disclosure.

FIG. 2B illustrates a side cross-sectional view of an ampoule with a blocker a distance above the bottom of the container, according to one or more embodiments of the disclosure.

FIG. 2C illustrates a side cross-sectional view of an ampoule with a blocker with three openings, according to one or more embodiments of the disclosure.

FIG. 2D illustrates a side-cross sectional view of a trapezoidal-shaped ampoule with a blocker, according to one or more embodiments of the disclosure.

FIG. 3A illustrates a top-down view of an ampoule with a blocker, the perspective from a viewer above the ampoule, according to one or more embodiments of the disclosure.

FIG. 3B illustrates a top-down view of an ampoule with a blocker, the perspective from a viewer at around ⅔ the height of the ampoule, according to one or more embodiments of the disclosure.

FIG. 3C illustrates a top-down view of an ampoule with a blocker, the perspective from a viewer at around ⅓ the height of the ampoule, according to one or more embodiments of the disclosure.

FIG. 4 illustrates a top-down view of an ampoule with a blocker that does not completely contact the sidewall, according to one or more embodiments of the disclosure.

FIG. 5 illustrates the decrease in surface area of a solid precursor as the precursor is consumed and sinters, according to one or more embodiments of the disclosure.

FIG. 6 compares the difference in wafer deposition thickness as the precursor is consumed between an ampoule with a blocker versus an ampoule without a blocker.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

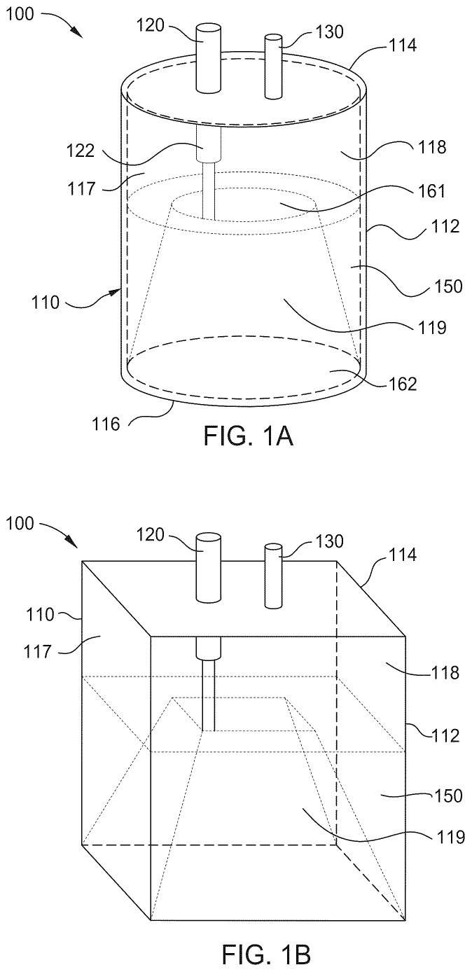

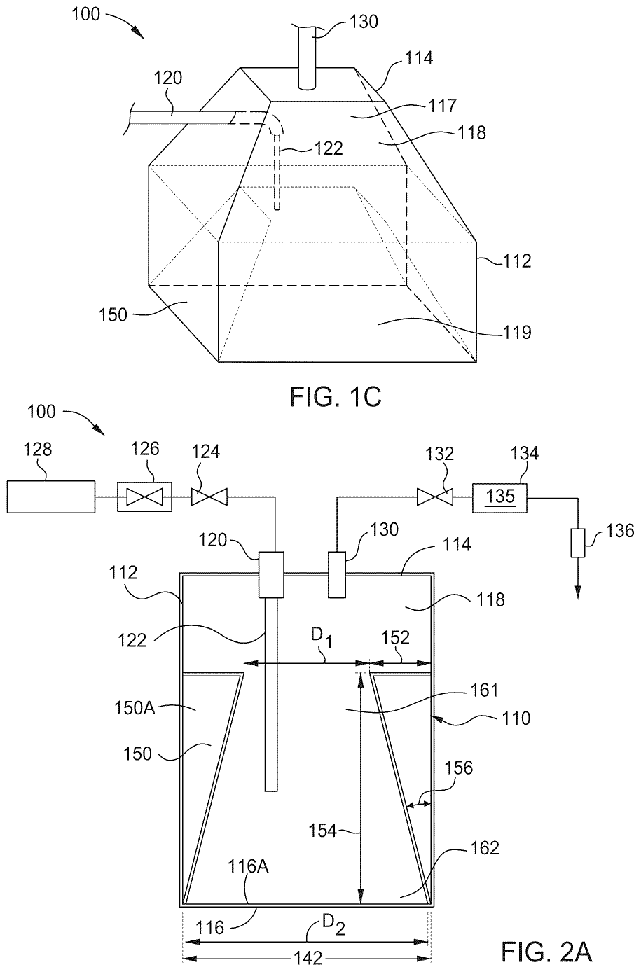

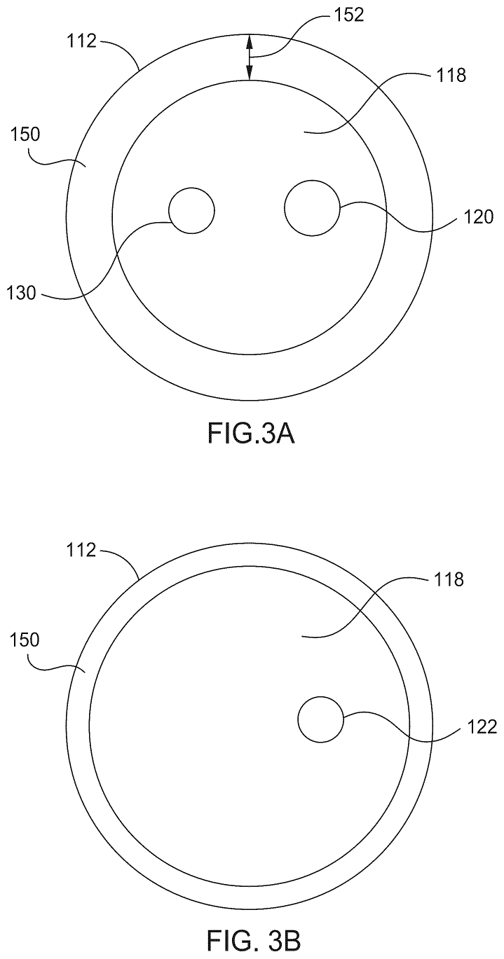

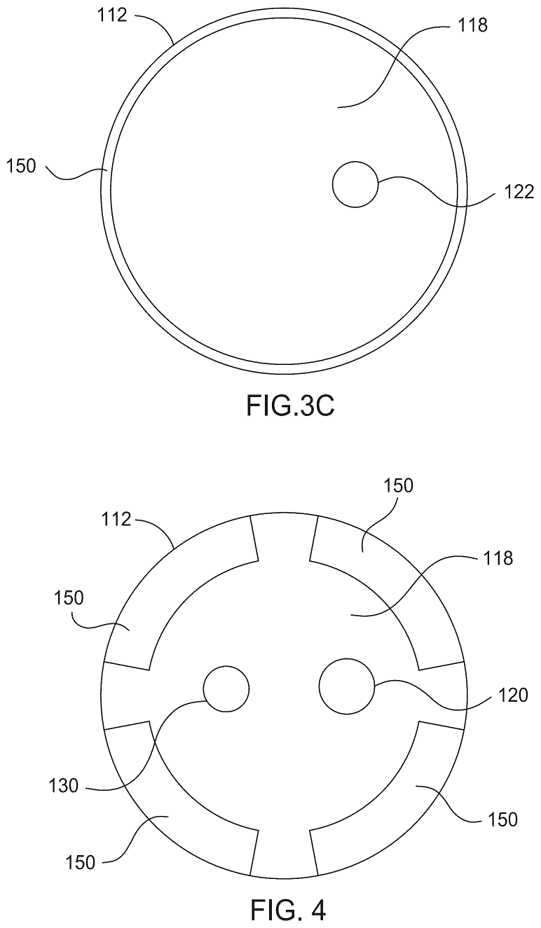

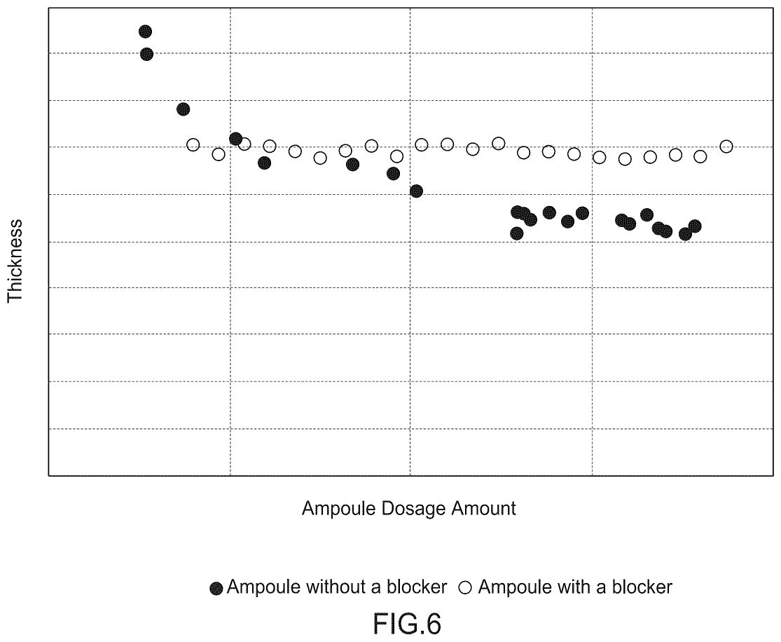

The following disclosure describes systems, methods, and apparatuses used for delivery of chemical precursors. Certain details are set forth in the following description and in FIGS. 1-6 to provide a thorough understanding of various implementations of the disclosure.

Many of the details, dimensions, angles, and other features shown in the Figures are merely illustrative of particular implementations. Accordingly, other implementations can have other details, components, dimensions, angles, and features without departing from the spirit or scope of the present disclosure. In addition, further implementations of the disclosure can be practiced without several of the details described below.

Embodiments of the disclosure provided herein generally relate to a system and hardware used to deliver precursors during a chemical vapor deposition (CVD) process, an atomic layer deposition (ALD) process, or other useful process that requires the delivery of a precursor containing process gas to a processing chamber. Embodiments of the disclosure can be useful for the delivery of a process gas during a gap fill or capping type of deposition process. In one example, embodiments of the present disclosure relate to the delivery of a molybdenum precursor, such as molybdenum pentachloride (MoCl₅) vapor containing precursor during a molybdenum gap fill deposition process.

FIG. 1 illustrates an ampoule 100 according to one or more embodiments. The ampoule 100 includes a container 110, an inlet port 120, and an outlet port 130. The ampoule 100 may be used with semiconductor manufacturing precursors. For example, the ampoule 100 may be utilized to provide a precursor 140 during the processing of a substrate. The ampoule 100 may provide the precursor 140 to a process chamber to deposit a material on a substrate. As noted above, a layer may be formed due to the delivery of the precursor 140 by any suitable method including chemical layer deposition (CVD) and atomic layer deposition (ALD). The precursor 140 is vaporized in the ampoule 100 and provided into a process chamber or other process environment in a vaporized state for use in a deposition or other semiconductor fabrication process.

The container 110 may include a sidewall 112, lid 114, and bottom 116 defining a cavity 118, or also referred to herein as an internal region 118. The internal region 118 includes a top end, bottom end, and a frustum-shaped internal region 119, which is described below, positioned between the top end and the bottom end. In some embodiments, the cavity 118 includes a head space region 117 and the frustum-shaped internal region 119 (FIG. 1A). The container 110 may be formed of a material such as a metal (e.g., stainless steel, aluminum, etc.), ceramic, glass, or other useful material. The lid 114 may be secured to the sidewall 112 to fully enclose the cavity 118. Ports 120, 130 may be included to allow fluids to flow in and out of the enclosed cavity 118. For example, the inlet port 120 and outlet port 130 may pass through the lid 114. In some embodiments, the container 110 includes two or more inlet ports 120 and/or two or more outlet ports 130. The ports 120,130 are generally sealable to allow the cavity 118 to be isolated from the surrounding environment. Further, one or more ports may be placed within one or more of the sidewalls 112, the lid 114, and the bottom 116. For example, a refill port may be placed within the sidewall 112 or the lid 114 and utilized to refill the container 110 with additional precursors 140.

In some embodiments, the inlet port 120 is connected to a diffuser 122 to lower the entry point of the carrier gas into the cavity 118. A lower entry point may prevent the carrier gas from flowing from the inlet port 120 to the outlet port 130 without carrying or interacting with the precursor 140. In some embodiments, the inlet port 120 is connected to a diffuser 122 and further connected to a nozzle to disperse the carrier gas throughout the cavity 118. In many embodiments with a liquid precursor, a nozzle is used to bubble the carrier gas through the liquid precursor. However, a nozzle may still be used in embodiments with a solid precursor.

The lid 114 may be a separate component from the sidewall 112 and attached to the sidewall 112 to define the cavity 118. For example, the lid 114 may connect to the sidewall 112 through a welding process or through the use of one or more bolts or other connecting devices. While not shown, a sealing member may be disposed between the lid 114 and the sidewall 112 to prevent leakage of atmospheric gases into the ampoule 100 or vapors and/or carrier gases from leaking out of the ampoule 100. The sealing member may be an O-ring or other seal.

The inlet port 120 provides a connection to an external carrier gas source 128. Further, the inlet port 120 provides a passageway for carrier gasses to flow through the lid 114 and into the cavity 118. The inlet port 120 may include one or more inlet valves 124 that control the flow of gases through the inlet port 120 into the cavity 118. A mass flow controller (MFC) 126 may be coupled upstream of the one or more inlet valves 124 and may be configured to control the flow rate of the gas(es) provided to the inlet port 120 from a gas source 128.

The outlet port 130 allows a vaporized precursor to flow from the cavity 118 to a processing region 135 of a process chamber 134 or other process environment through one or more gas lines 192. Further, the outlet port 130 may provide a passageway for gases to flow out of the cavity 118 and through the lid 114. The outlet port 130 may include an outlet valve 132 that controls the flow of gases through the outlet port 130 and to the process chamber 134. The process chamber 190 can be coupled to an exhaust pump 136 that is configured to control the pressure in the processing region 135 of the process chamber 134.

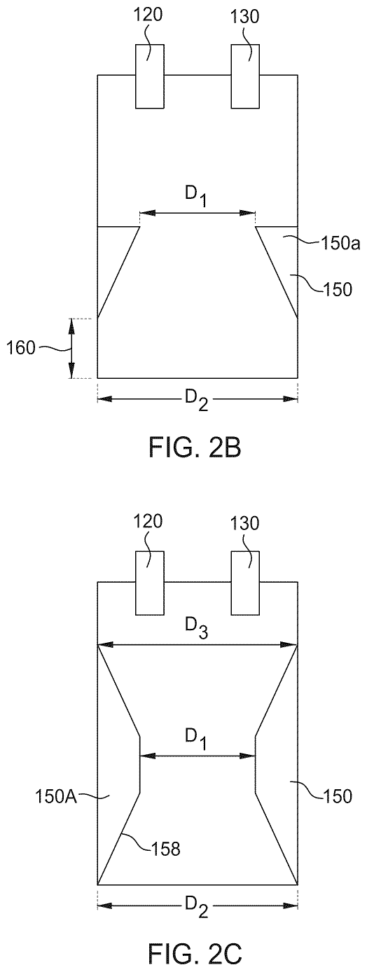

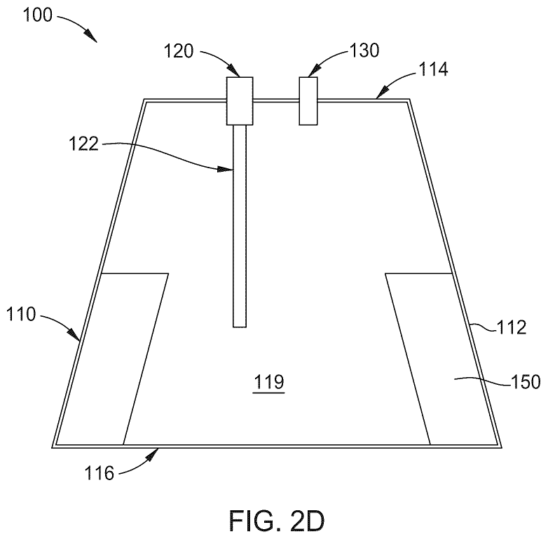

The container 110 may be substantially cylindrical in shape. Alternatively, the container 110 may have other useful shapes. In some embodiments the container 110 is substantially similar to a rectangular prism in shape, as illustrated in FIG. 1B. In some embodiments, the container 110 includes a combination of prism shapes such as a shape that includes a rectangular prism and a triangular prism shape, as illustrated in FIG. 1C. In some embodiments, the container 110 has a substantially cylindrical base that has a first interior diameter and a top region that has a second interior diameter that is smaller than the first interior diameter such that the container 110 has a conical shape or trapezoidal cross-sectional shape, as illustrated in FIG. 2D. In some embodiments, the container 110 is substantially similar to a combination of the aforementioned shapes or additional shapes not mentioned herein.

In one embodiment, where the container 110 includes a cylindrical shape the internal region may have a diameter 142 from about 1 cm to about 20 cm. In some embodiments, the container 110 has a diameter from about 1 cm to about 18 cm, about 1 cm to about 16 cm, about 1 cm to about 14 cm, about 1 cm to about 12 cm, about 1 cm to about 10 cm, about 1 cm to about 8 cm, about 1 cm to about 6 cm, about 1 cm to about 4 cm, about 5 cm to about 20 cm, or about 7 cm to about 20 cm.

In some embodiments, where the container 110 may have a height from about 1 cm to about 30 cm. In some embodiments, the container 110 has a height from about 1 cm to about 25 cm, about 1 cm to about 20 cm, about 1 cm to about 15 cm, about 3 cm to about 30 cm, about 3 cm to about 25 cm, about 3 cm to about 20 cm, about 3 cm to about 15 cm, about 5 cm to about 30 cm, about 5 cm to about 25 cm, about 5 cm to about 20 cm, about 5 cm to about 15 cm, about 7 cm to about 30 cm, about 7 cm to about 25 cm, about 7 cm to about 20 cm, about 7 cm to about 15 cm, about 10 cm to about 30 cm, about 10 cm to about 25 cm, about 10 cm to about 20 cm.

The container 110 may have a fill height of precursor 140 from about 0.5 cm to about 10 cm from an internal bottom surface 116A. In some embodiments, the container 110 has a fill height of precursor 140 from about 0.5 cm to about 9 cm, about 5 cm to about 10 cm, about 7 cm to about 10 cm, or about 9 cm to about 10 cm.

The ampoule 100 may be heated to vaporize the precursor 140 by any suitable heating device. In some embodiments, the ampoule 100 is heated by direct heating of the ampoule 100 by use of a resistive heater and/or lamps. In some embodiments, the carrier gas flowed through the inlet port 120 may be heated to increase the temperature of the precursor 140 in the cavity 118.

In some embodiments, the ampoule 100 is heated before the precursor 140 is added to the ampoule 100. In some embodiments, the ampoule 100 is heated after the precursor 140 is added to the ampoule 100, but before the carrier gas is flowed into the cavity 118 from the gas source 128. In these embodiments, the precursor 140 may sinter and form clumps before the carrier gas is flowed into the cavity 118. In some embodiments, the ampoule 100 is heated after the carrier gas is flowed into the cavity 118.

The ampoule 100 may be heated to a temperature between about 60 degrees Celsius and about 130 degrees Celsius. In some embodiments, the ampoule 100 is heated to a temperature between about 60 degrees Celsius and about 65 degrees Celsius, about 65 degrees Celsius and about 70 degrees Celsius, about 70 degrees Celsius and about 75 degrees Celsius, about 75 degrees Celsius and about 80 degrees Celsius, about 80 degrees Celsius and about 85 degrees Celsius, about 85 degrees Celsius and about 90 degrees Celsius, about 90 degrees Celsius and about 95 degrees Celsius, about 95 degrees Celsius and about 100 degrees Celsius, about 100 degrees Celsius and about 105 degrees Celsius, about 105 degrees Celsius and about 110 degrees Celsius, about 110 degrees Celsius and about 115 degrees Celsius, about 115 degrees Celsius and about 120 degrees Celsius, about 120 degrees Celsius and about 125 degrees Celsius, about 125 degrees Celsius and about 130 degrees Celsius, or about 130 degrees Celsius and about 135 degrees Celsius.

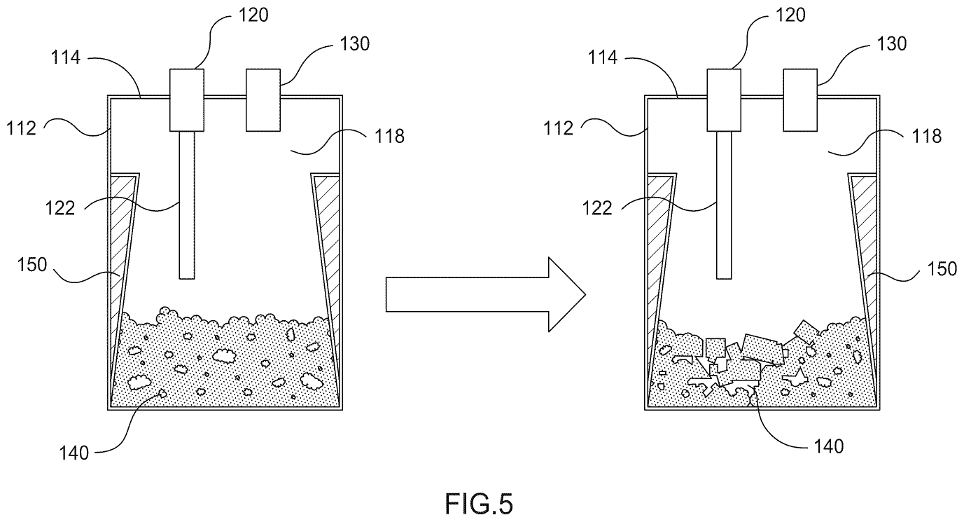

In some embodiments, the vaporized precursor 140 flows through the outlet port 130 to a showerhead apparatus (not shown) in the process chamber 134, which is used to deposit a layer onto a wafer during an ALD process. The thickness of the layer formed on the wafer is directly related to the flow rate of the vaporized precursor 140 carried into the process region 135 of the process chamber 134. Further, the flow rate of the vaporized precursor 140 is directly related to the surface area and vapor pressure of the precursor 140 disposed within the cavity 118 of the container 110. As the precursor 140 is consumed by the carrier gas sweeping the vaporized or sublimated precursor out of the cavity 118 and through the outlet port 130, the surface area of the non-vaporized and non-sublimated precursor 140 decreases often due to agglomeration or sintering of the precursor material. The clumped solid precursor 140 has a lower surface area than if the solid precursor 140 was non-clumped and in a finer powder state. FIG. 5 illustrates the decreased amount of precursor 140 surface area in the container 110 as the precursor 140 is consumed and sinters, as shown by the change in size of the clumps of precursor disposed at the bottom of the cavity 118. As the surface area of the precursor 140 decreases, the amount of the vaporized precursor in a constant flow of a carrier gas decreases. Accordingly, the deposited thickness of the wafer decreases as the precursor delivery process progresses. A blocker 150, or blocker feature 150, may be added to the ampoule 100 to create a more uniform surface area of the precursor 140 in the container 110 as the precursor 140 is consumed, agglomerates, and sinters.

Accordingly, in some embodiments, the ampoule 100 also includes a blocker 150 located in the cavity 118. The blocker 150 is connected to the interior of the sidewall 112 via any suitable connection method including a welding process or through the use of one or more bolts or other connecting devices. The blocker 150 may also be connected to the interior of the sidewall 112 via an adhesion method or a form of chemical bonding or brazing to the sidewall 112 of the ampoule 100. The blocker 150 may be connected to all of the contact points of the sidewall 112, or only certain portions of the sidewall 112. One example of the blocker not contacting the entire sidewall surface can be seen in the top view illustrated in FIG. 4. The blocker 150 includes a plurality of segments disposed around a perimeter of the internal region 118 at the first end. In this example, the blocker 150 includes two or more segments, such as four equally spaced apart segments, as shown in FIG. 4.

Additionally, in some embodiments including the embodiment disclosed in FIG. 2D, the ampoule 100 does not include a blocker 150. To increase the area of the cross section of the ampoule 100 along the height of the ampoule 100, the sidewalls 112 of the ampoule 100 are angled outwards in such a way that there is a smaller diameter at an upper portion of the ampoule 100 and a larger diameter at a lower portion of the ampoule 100.

The blocker 150 may have a cylindrical-shaped body, a frustum-shaped internal region, a blocker height 154, a first diameter D₁, a second diameter D₂, and a blocker width 152. The width of the blocker 150 decreases as the height 154 of the blocker 150 decreases. Accordingly, the first diameter D₁ may coincide with the largest width of the blocker 150 and the width of the blocker 150 at the bottom 116 of the container 110 may be the narrowest. Further, the first diameter D₁ is greater than the second diameter D₂. In some embodiments, the second diameter D₂ is substantially equal to the diameter 142 of the internal region 118.

The frustum-shaped internal region 119 may be defined as the portion of a cone which remains after an upper section portion of the cone is removed above a plane that divides an upper and lower portion of the cone, wherein the plane is generally aligned parallel to the base of the cone (FIG. 1A). Additionally, the frustum-shaped internal region 119 may alternately be defined as the portion of a trapezoidal prism which remains after an upper section portion of the trapezoidal prism is removed above a plane dividing the upper and lower portions of the trapezoidal prism, wherein the plane is generally aligned parallel to the base of the triangular prism (FIGS. 1B and 1C). Further, the frustum-shaped internal region 119 may be defined as the portion of any three dimensional shape (e.g., triangular prism, pentagonal prism, hexagonal prism, octagonal prism, etc. with tapered side walls) which remains after an upper section portion of the three-dimensional shape is removed from a plane dividing the upper and lower portions of the three dimensional shape, wherein the plane is generally aligned parallel to the base of the three dimensional shape.

The frustum-shaped internal region 119 comprises a first opening 161 positioned at a first end of the frustum-shaped internal region 119. In some embodiments, the first end is positioned a first distance (e.g., vertical distance) from the lid 114 to form the head space region 117. In some embodiments, the first end is the top of the blocker that defines the frustum-shaped internal region. The frustum-shaped internal region also comprises a second opening 162 positioned at a second end of the frustum-shaped internal region. In some embodiments, the second end is positioned below the first end a distance away from the first end. In some embodiments, the distance between the first end and the second end could be defined as the height 154 of the blocker 150, as illustrated in FIG. 2A.

In some embodiments, the first opening 161 of a cone-shaped prism comprises a first area defined by a first diameter, D₁, and the second opening 162 comprises a second area defined by a second diameter, D₂. In some embodiments, the frustum-shaped internal region comprises three openings, each comprising an area defined by a diameter, D₁, D₂, D₃, where the diameters D₁ and D₃ are positioned at opposing ends of the frustum-shaped internal region and the diameter D₂, is disposed between the diameters D₁ and D₃. In some embodiments, the first opening 161 comprises a first area defined by a first two-dimensional shape (e.g., circular or non-circular shape such as an oval, triangle, square, rectangle, pentagon, hexagon, etc.) and the second opening 162 comprises a second area defined by a second two-dimensional shape (e.g., circular or non-circular shape such as an oval, triangle, square, rectangle, pentagon, hexagon, etc. shape). In one example, the first two-dimensional shape and the second two-dimensional shape both include the same two-dimensional shape, such as a circle, oval, square or rectangle shape. In one embodiment, the first opening 161 includes an opening at a first end of the frustum-shaped region that has a cross-sectional area that is between 3.1 cm² and 3,000 cm², such as between 80 cm² and 2,000 cm², or between 500 cm² and 1,260 cm².

In some embodiments, the first area of the first opening 161 and a second area of the second opening 162 are measured in a direction parallel to a first plane. Further, an area of the frustum-shaped region measured in the direction parallel to the first plane increases as the frustum-shaped region extends from the first end to the second end.

In some embodiments, the blocker 150 includes a first area to second area ratio between about 0.001 and about 1, such as an irrational number less than about 0.9, or less than about 0.5, or less than about 0.1, or less than about 0.05, or even less than about 0.01. In some embodiments, the blocker 150 includes a first area to second area ratio between about 0.75 and about 0.99.

In some embodiments, the blocker width 152 may be between about 0.1 cm and about 5 cm, such as between about 0.1 cm and about 2 cm, or between about 0.1 cm and about 1 cm, or between about 0.1 and about 0.5 cm

In some embodiments, the width of the blocker 150 decreases linearly with height 154. The rate at which the width of the blocker 150 decreases as the height 154 decreasesmay be represented by an angle theta (Θ) 156. Theta 156 is the angle of the inner surface 158 of the blocker 150 relative to the inner surface of the sidewall 112. Additionally, theta 156 can be defined as the arctangent of the quotient of the blocker width 152 and the height 154. Furthermore, in some embodiments, the width of the blocker 150 decreases differentially. In any of the embodiments and including those embodiments in which the width of the blocker 150 does not decrease linearly, the rate at which the width of the blocker 150 as the height 154 decreasesmay be altered as a function of various parameters including the density of the precursor 140, the amount of precursor 140 to be loaded into the container 110 (or the fill height of the precursor 140 in the container 110), or the desired flow rate of the vaporized precursor 140 through the outlet port 130.

Theta 156 may be between about 0.1 degrees and about 60 degrees. In some embodiments, theta is between about 1 degree and about 45 degrees, about 15 degrees to about 35 degrees, or about 25 degrees to about 30 degrees.

In some embodiments, the height 154 of the blocker 150 may be around 1 cm less than the height of the container 110. The height 154 of the blocker 150 may be from about 1 cm to about 30 cm. In some embodiments, the height 154 is from about 1 cm to about 15 cm, about 1 cm to about 20 cm, about 1 cm to about 25 cm, about 5 cm to about 10 cm, about 5 cm to about 15 cm, about 5 cm to about 20 cm, about 10 cm to about 15 cm, about 10 cm to about 20 cm, about 10 cm to about 25 cm, about 10 cm to about 30 cm, about 1.5 cm to about 10 cm, about 5 cm to about 10 cm, about 7 cm to about 11 cm, about 7 cm to about 10 cm, or about 10 cm to about 11 cm.

In some embodiments, the blocker 150 has a cross-sectional shape from a side view similar to a trapezoid or triangle. In some embodiments, the blocker 150 has a cross-sectional shape dissimilar to any traditional geometric shape and instead the inner surface 158 may have curvature and sudden decreases in width that are not observed in traditional geometric shapes. In one such embodiment the cross-sectional shape of the blocker 150 may consist of an arc at the top, a straight line with a gradual slope in the middle, and then a straight line with a steep slope at the bottom. Any combination of shapes and structures may be chosen to control the rate that the vaporized precursor 140 flows through the outlet port 130.

In some embodiments, the blocker 150 includes a first diameter D1 to second diameter D₂ ratio where the first diameter D₁ is less than the second diameter D₂. In one example, the first diameter D₁ to second diameter D₂ ratio is greater than about 0.1 and less than 1, such as greater than 0.2 and less than 1, such as greater than 0.3 and less than 1, such as greater than 0.4 and less than 1, such as greater than 0.5 and less than 1, such as greater than 0.75 and less than 1, such as greater than 0.8 and less than 1, or greater than 0.9 and less than 1, or greater than 0.95 and less than 1, or greater than 0.97 and less than 1, such as between about 0.75 about 0.99, or between about 0.8 about 0.99, or between about 0.9 about 0.99, or between about 0.9 about 0.97.

In some embodiments, the blocker 150 includes a blocker width 152 to blocker height 154 ratio that is between about 0.001 and about 1, such as an irrational number less than about 0.9, or less than about 0.5, or less than about 0.1, or less than about 0.05, or even less than about 0.01.

In some embodiments, the blocker 150 includes a blocker height 154 to height of the container 110 ratio that is between about 0.001 and about 1, such as an irrational number less than about 0.9, or less than about 0.5, or less than about 0.1, or less than about 0.05, or even less than about 0.01.

In some embodiments, the blocker 150 includes a blocker height 154 to height of the internal region 118 of the container 110 ratio that is between about 0.001 and about 1, such as an irrational number less than about 0.9, or less than about 0.5, or less than about 0.1, or less than about 0.05, or even less than about 0.01.

In some embodiments, the top surface of the blocker 150 is substantially parallel to the lid 114 of the container 110. In some embodiments, the top surface of the blocker 150 may slope down towards the sidewall 112 of the container 110. In some embodiments, the top surface of the blocker 150 may slope up towards the sidewall 112 of the container 110. In other embodiments, the top surface of the blocker 150 may be concave or convex.

In some embodiments, the blocker 150 may contact the bottom 116 of the container 110. In some embodiments, the blocker 150 may be positioned above the bottom 116 of the container 110 by an offset distance 160. In some embodiments, the blocker 150 may contact the lid 114 or be formed as part the lid 114 of the container 110. In some embodiments, the blocker 150 may be spaced apart from the lid 114, and thus not contact the lid 114 of the container 110.

The blocker 150 may be hollow, thin walled, or made of a solid material. The blocker 150 may be made of any suitable material, including materials that will not react with the precursor 140. In some embodiments, the internal volume 151 of the blocker 150 may include resistive heating elements or lamps that are positioned about a vertical central axis of the blocker 150. In some embodiments, the blocker 150 is made of stainless steel, ceramic, glass, or other useful materials.

The precursor 140 may be in a solid state, liquid state, or a combination of both as a slurry. In one or more embodiments, the precursor 140 can be molybdenum pentachloride (MoCl₅) that is disposed in a powder, granular, or porous solid form. However, the precursor 140 may also be formed from a solid that includes significant non-regular topography variations.

In some embodiments, the density of the precursor 140 is between about 1 g/cm³ and about 5 g/cm³, between about 1 g/cm³ and about 3 g/cm³, between about 2.5 g/cm³ and about 3 g/cm³, between about 1 g/cm³ and about 2.5 g/cm³, between about 1.5 g/cm³ and about 2.5 g/cm³, between about 1.5 g/cm³ and about 2 g/cm³, between about 1.6 g/cm³ and about 1.8 g/cm³, or between about 1.7 g/cm³ and about 1.75 g/cm³.

In some embodiments, the desired thickness of a layer formed on a wafer during a deposition process is between about 2 angstroms and about 10,000 angstroms.

In some embodiments, the carrier gas to flow through the outlet port 130 is argon, nitrogen, helium, or other useful gas.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements, and vice versa, are contemplated.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits, and ranges appear in one or more claims below.

Certain embodiments and features have been described using the term “about” with a numerical value. When the term “about” is used in conjunction with a numerical value, it should be construed as indicating any numerical value within 10% of the stated numerical value.

What is claimed is:

1. A precursor delivery system, comprising:
a container comprising one or more walls that define an internal region, wherein the internal region comprises a top end, a bottom end, and a frustum-shaped region positioned between the top end and the bottom end, wherein the frustum-shaped region comprises:
a first opening positioned at a first end of the frustum-shaped region; and
a second opening positioned at a second end of the frustum-shaped region, wherein:
the first opening comprises a first area and the second opening comprises a second area; and
the second end is positioned a first distance from the first end and below the first end.

2. The precursor delivery system of claim 1, wherein the frustum-shaped region comprises a ratio of the first area to the second area between about 0.75 and about 0.99.

3. The precursor delivery system of claim 1, wherein the frustum-shaped region comprises a ratio of the first area to the second area between about 0.5 and about 0.75.

4. The precursor delivery system of claim 1, wherein the frustum-shaped region comprises a ratio of the first area to the second area between about 0.2 and about 0.5.

5. The precursor delivery system of claim 1, wherein the first area is defined by a first diameter and the second area is defined by a second diameter.

6. The precursor delivery system of claim 5, wherein the second diameter is substantially equal to a diameter of the internal region at the second end.

7. The precursor delivery system of claim 1, wherein the frustum-shaped region is defined by a surface of a blocker feature positioned within the internal region, wherein the blocker feature comprises:
the first opening being positioned at a first end of the blocker feature;
the second opening being positioned at a second end of the blocker feature; and
a blocker feature height to a container internal region height ratio that is between about 0.5 and about 0.9.

8. The precursor delivery system of claim 7, wherein the container comprises one or more inlet ports.

9. The precursor delivery system of claim 8, wherein the container comprises one or more outlet ports.

10. The precursor delivery system of claim 9, wherein the container is coupled to an atomic layer deposition chamber.

11. The precursor delivery system of claim 1, wherein the frustum-shaped region is defined by a surface of a blocker feature positioned within the internal region, wherein the blocker feature comprises:
the first opening being positioned at a first end of the blocker feature;
the second opening being positioned at a second end of the blocker feature; and
the blocker feature comprises stainless steel, ceramic, glass, or a combination thereof.

12. The precursor delivery system of claim 1, wherein the frustum-shaped region is defined by a surface of a blocker feature positioned within the internal region, wherein the blocker feature comprises:
the first opening being positioned at a first end of the blocker feature;
the second opening being positioned at a second end of the blocker feature; and
the blocker feature comprises a plurality of segments disposed around a perimeter of the internal region at the first end.

13. The precursor delivery system of claim 1, wherein
the first area of the first opening and the second area of the second opening are measured in a direction parallel to a first plane; and
an area of the frustum-shaped region measured in the direction parallel to the first plane increases as the frustum-shaped region extends from the first end to the second end.

14. The precursor delivery system of claim 1, wherein
the first area of the first opening and the second area of the second opening are measured in a direction parallel to a first plane; and
an area of the frustum-shaped region measured in the direction parallel to the first plane increases non-linearly as the frustum-shaped region extends from the first end to the second end.

15. An ampoule, comprising:
a container, comprising:
a lid comprising an inlet port and an outlet port;
at least one sidewall;
a bottom; and
an internal region defined as the space enclosed by the lid, sidewall, and bottom; and
a blocker feature positioned inside the internal region of the container, the blocker feature comprising a frustum-shaped region, wherein the frustum-shaped region comprises:
a first opening positioned at a first end of the frustum-shaped region; and
a second opening positioned at a second end of the frustum-shaped region, wherein:
the first opening comprises a first area and the second opening comprises a second area; and
the second end is positioned a first distance from the first end and below the first end.

16. The ampoule of claim 15, wherein the frustum-shaped region comprises a ratio of the first area to the second area between about 0.75 and about 0.99.

17. The ampoule of claim 15, wherein the blocker feature comprises stainless steel, ceramic, glass, or a combination thereof.

18. The ampoule of claim 15, wherein the blocker feature comprises a plurality of segments disposed around a perimeter of the internal region at the first end.

19. An ampoule blocker configured to be positioned in a container coupled to a deposition chamber, comprising a frustum-shaped cavity, wherein the frustum-shaped cavity comprises:
a first opening positioned at a first end of the frustum-shaped cavity; and
a second opening positioned at a second end of the frustum-shaped cavity, wherein:
the first opening comprises a first area and the second opening comprises a second area;
the second end is positioned a first distance from the first end and below the first end; and
a ratio of the first area to the second area is between about 0.75 and about 0.99.

20. The ampoule blocker of claim 19, wherein the ampoule blocker is made of stainless steel, ceramic, glass, or any combination thereof.
